(19) United States
(12) Patent Application Publication
(10) Pub. No.: US 2003/0077849 A1
(43) Pub. Date: Apr. 24, 2003

(54) Method for fabricating ohmic contact layer in semiconductor devices

(76) Inventors: Yet-Zen Liu, Westlake Village, CA (US); Yu Dong Li, Thousand Oaks, CA (US)

Correspondence Address: KLEIN, O'NEILL & SINGH, 2 PARK PLAZA, SUITE 510, IRVINE, CA, 92614, US

(21) Appl. No.: 10/055,221

(22) Filed: Oct. 19, 2001

(51) Int. Cl. H01L 21/00; H01L 21/44

(52) U.S. Cl. 438/31; 438/39

(57) ABSTRACT

A method for depositing ohmic contact material in a semiconductor, ridge type waveguide device is provided. Ohmic contact material is deposited on a semiconductor wafer and a ridge is fabricated with the deposited material and a first layer of photoresist material. A dielectric material layer is deposited on the ridge and a second photoresist material layer is deposited on the dielectric material layer. The second photoresist material layer is opened to expose the ohmic contact layer and any extra metal overhang is removed to expose the self-aligned ohmic contact layer on the ridge.

### BACKGROUND OF THE INVENTION

1. Field of the Invention

The present invention relates to devices and methods used in fiber optic networks and more particularly, to fabricating semiconductor ridge type waveguide devices.

2. Background

Semiconductor lasers and photodetectors are used extensively in fiber optic networks. Waveguides in such devices guide the flow of electromagnetic energy in a direction parallel to the waveguide axis. One type of waveguide used in such devices is the “ridge type waveguide.” FIG. 1A shows a cross-sectional view of a conventional ridge type waveguide 100. Turning in detail to FIG. 1A, a laminated structure is sequentially formed by a n-type cladding layer 104, a waveguide core layer 103, a p-type cladding layer 102 and an ohmic contact layer 101, on a semiconductor substrate 105. An electrode (not shown) is mounted on ohmic contact layer 101 and on the back surface of layer 105.

In the case of semiconductor lasers, a forward bias is applied between layer 102 and 104 that generates optical energy in layer 103. In the case of a semiconductor photodetector, a reverse bias is applied between layer 102 and 104 and incident light (not shown) guided to layer 103 is converted into a photoelectric signal.

Proper ohmic contact minimizes resistive heating in semiconductor lasers resulting from contact resistance, and also reduces the RC time constant for photodetectors. Typically, ohmic contact layer 101 is 1.0 to 2.5 microns wide.

Conventional process steps for fabricating ohmic contact layer 101 are as follows:

(i) a ridge shaped waveguide surface is created by chemically etching a semiconductor wafer;

(ii) a dielectric material layer is deposited on the wafer;

(iii) a photoresist material layer is added over the dielectric layer;

(iv) an ohmic contact layer area is exposed using expensive and complicated photolithographic alignment and using UV light energy; and

(v) thereafter, ohmic contact material is deposited on the ridge.

FIGS. 1B through 1D illustrate the foregoing conventional process steps for fabricating ohmic contact layer 101.

Turning in detail to FIG. 1B, is a cross-sectional view of a ridge type, waveguide 106 with ohmic contact area 107 covered with photoresist material 108. When UV light 109 is applied it creates an opening 107A (using expensive and complicated photolithographic alignment process) which should be equal to ohmic contact area 107, as illustrated in the cross-sectional view of FIG. 1C. Thereafter, as illustrated in FIG. 1D, ohmic contact material 110 is deposited on top of the exposed ridge 106A and photoresist material layer 108. The foregoing conventional techniques for depositing ohmic contact material 110 are based on physical and/or chemical vapor deposition techniques.

The foregoing process has disadvantages. If opening 107A (as shown in FIG. 1C) in the photoresist material layer 108, after UV light 109 is applied, is smaller than ohmic contact layer area 107, the net ohmic contact area is reduced. This increases contact resistance.

If opening 107A in photoresist material layer 108 is greater than ohmic contact area 107, contact layer 110 may be electrically shorted to waveguide 106. This may permanently damage the semi conductor wafer.

Therefore, there is a need for a reliable process for fabricating the ohmic contact layer that does not depend upon expensive and complicated photolithographic alignment.

### SUMMARY OF THE INVENTION

There is provided in accordance with one aspect of the present invention, a method for depositing ohmic contact material in a ridge waveguide device that addresses the foregoing deficiencies. Ohmic contact material is deposited on a semiconductor wafer and a ridge is fabricated using a first layer of photoresist material. A dielectric material layer is deposited on the ridge and a second photoresist material layer is deposited on the dielectric material layer. The second photoresist material layer is opened to expose a self aligned ohmic contact layer.

In accordance with another aspect of the present invention, there is provided a method wherein expensive and tedious photolithographic alignment is not required since ohmic contact material is deposited before the ridge is created, and the ohmic contact area is self-aligned with respect to the ridge.

This brief summary has been provided so that the nature of the invention may be understood quickly. A more complete understanding of the invention can be obtained by reference to the following detailed description of the preferred embodiments thereof in connection with the attached drawings.

### BRIEF DESCRIPTION OF THE DRAWINGS

FIG. 1A described above, is an illustration of a typical ridge type waveguide structure.

FIGS. 1B through 1D as described above, illustrate conventional process steps for depositing ohmic contact material on a ridge of a ridge type waveguide device.

FIG. 2 is a flow diagram showing process steps for depositing ohmic contact material in an embodiment according to the present invention.

FIG. 3 is a cross-sectional view of a semiconductor starting wafer showing ohmic contact material deposited on the wafer, according to an embodiment of the present invention.

FIG. 4 is a cross-sectional view of the wafer in FIG. 3 showing photoresist material deposited on the photodetector wafer.

FIG. 5 is a cross-sectional view of the wafer in FIG. 4 showing an etched ridge on the wafer.

FIG. 6 is a cross-sectional view of the wafer in FIG. 5 showing a dielectric layer deposited on the etched wafer surface.

FIG. 7 is a cross-sectional view of the wafer in FIG. 6 showing photoresist material deposited on the dielectric layer with an opening.

FIG. 8 is a cross-sectional view of the wafer in FIG. 7 showing metal overhang after the photoresist layer is removed.

FIG. 9 is a cross-sectional view of the wafer in FIG. 8 showing a self aligned ohmic contact layer deposited over the ridge.

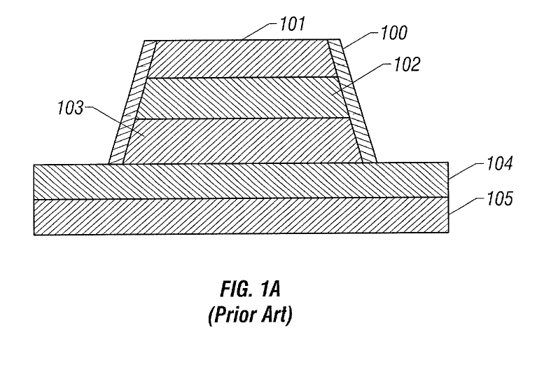

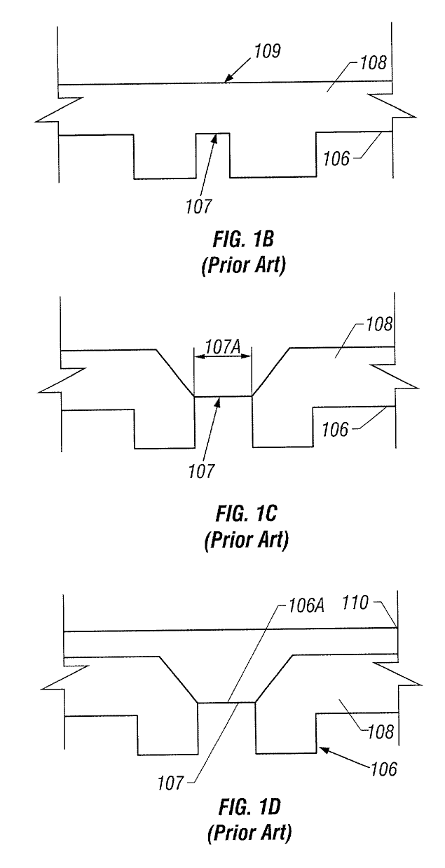

Features appearing in multiple figures with the same reference numeral are the same unless otherwise indicated.

### DETAILED DESCRIPTION

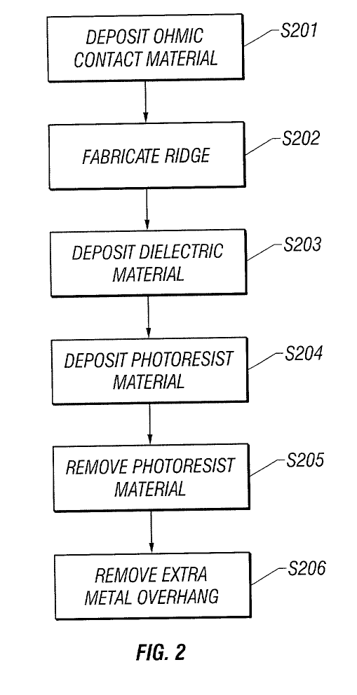

In one aspect of the present invention a process is provided such that expensive and tedious photolithographic alignment is not required and a self-aligned ohmic contact layer is created. Referring to the process flow diagram of FIG. 2 for depositing ohmic contact material, according to one aspect of the present invention comprising the steps of; depositing ohmic contact material on a semiconductor wafer, forming a ridge on the semiconductor by a first layer of photoresist material; creating an opening in the dielectric material and removing any extra photoresist material; and removing any extra metal overhang, leaving a self aligned ohmic contact layer on the ridge created on the semiconductor wafer.

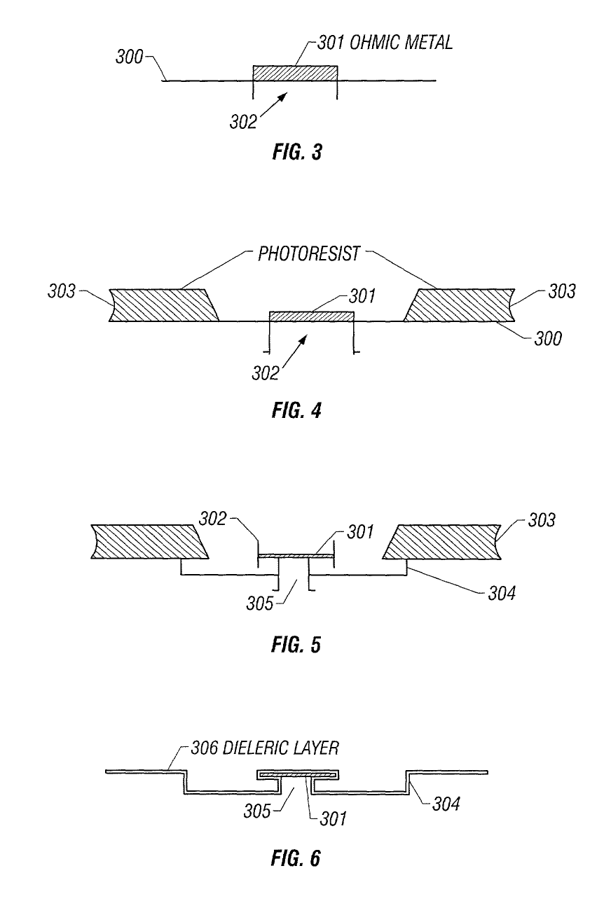

Turning in detail to FIG. 2, in step S201, ohmic contact material is deposited on a semiconductor wafer (“wafer”). FIG. 3 shows ohmic contact material 301 deposited on wafer 300 on area 302 (“Ohmic area 302”). Ohmic area 302 is greater than the ohmic contact area 305 (FIG. 5). Typically, ohmic area 302 width, ranges approximately between 3.5 to 4.5 microns. It is noteworthy that the present invention is not limited to any particular range of ohmic area 302 width, and may be used without limitation, for any ohmic area 302 width.

Various techniques may be used to deposit ohmic contact material in step S201. Some of the techniques, without limitation, are: sputtering or vacuum evaporation (physical deposition techniques) or chemical vapor deposition techniques. It is noteworthy that the invention is not limited to foregoing processes, other processes may be used to deposit ohmic contact material in step S201.

Sputtering involves the use of plasma to introduce a source material into a vapor state. The plasma consists of high density gaseous ions. When the plasma strikes the surface of the source material, it has enough energy to erode particles of the source material into a vapor or gaseous phase. The vapor phase can then be deposited.

Vacuum evaporation may also be used to deposit ohmic contact material in step S201. Aluminum and gold are heated to the point of vaporization, and then evaporated to form a thin film covering wafer 300. All ohmic contact material 301 is deposited under vacuum or very controlled atmosphere

Chemical vapor deposition is a process by which insulating or conducting films are deposited on a substrate by using reactant gases and an energy source that produces a gas-phase chemical reaction. The energy source may be thermal, optical or plasma in nature. Plasma enhanced, chemical vapor deposition (PECVD) may be used to deposit conducting films, like ohmic contact material 301.

In step S202, a ridge is formed on wafer 300. Photoresist material 303 and ohmic contact material 301 are used as masks to etch two channels to form the desired ridge. FIG. 4 shows photoresist material 303 deposited on wafer 300. FIG. 5 shows ridge 304 with ohmic contact area 305 where ohmic contact area 305 is less than ohmic area 302; typically the width of ohmic contact area 305 is 1.0 to 2.5 microns. It is noteworthy that the present invention is not limited to any particular range of ohmic contact area 305 width, and may be used without limitation, for any ohmic contact area 305 width.

In step S203, dielectric material is deposited on ridge 304. Generally PECVD process is used to deposit the dielectric material. Other methods for depositing dielectric material are vacuum evaporation and sputtering. FIG. 6 shows dielectric material layer 306 deposited on ridge 304. It is noteworthy that the present invention is not limited to PECVD process, and may be used without limitation, with any other process that may deposit dielectric material layer 306 deposited on ridge 304.

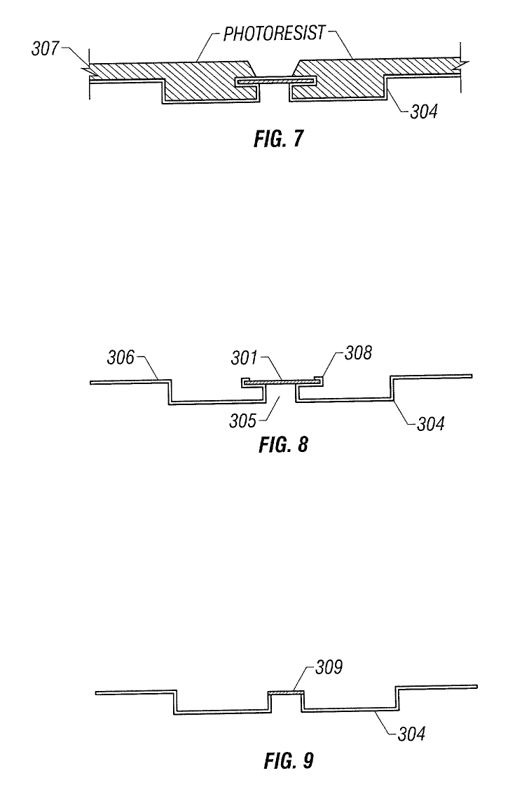

In step S204, a second layer of photoresist material is deposited on dielectric material layer 306. PECVD process may be used to deposit the photoresist material. FIG. 7 shows photoresist material layer 307 deposited on dielectric material layer 306 after an opening in the photoresist is made over the ridge. It is noteworthy that the present invention is not limited to the PECVD process, and may be used without limitation, with any other process that may deposit photoresist material layer 307 on dielectric material layer 306.

In step S205, an opening is made in the dielectric material over the ridge and photoresist material is removed. The width of the opening is defined by the photoresist in step S204. FIG. 8 shows metal overhang 308 after photoresist material layer 307 is removed.

Photoresist material (in step S205) may be removed by dry etching. Typically, dry etching uses gas-phase reactants, inert or active ionic species or a mixture of the foregoing to remove unprotected layers of a substrate by chemical processes, physical processes, or a combination of these, respectively. Dry etching is an anistropic etch process, such that the etch rate may be varied in different directions. Plasma etching is a common dry etch technique that uses a RF plasma to generate chemically active etchants that form volatile etch species with the substrate. Ion etching is another example of dry etching that uses inert species (e.g. Ar ions) either in a beam or with a parallel plate sputtering system. Commercial photoresist stripper or acetone may be used to remove any extra photoresist material left after the foregoing opening is created. It is noteworthy that the invention is not limited to removing photoresist material by dry etching, any other process may be used to remove photoresist material 307.

In step S206, commercial ultrasonic process or solvent spray is used to remove any extra metal overhang, leaving a self-aligned, ohmic contact layer on ridge 304. FIG. 9 shows a self-aligned ohmic contact layer 309 over ridge 304.

One aspect of the present invention is that expensive photolithographic alignment is not required because ohmic contact material is deposited before the ridge is created, and hence the ohmic contact area is self-aligned with respect to the ridge.

While the present invention is described above with respect to what is currently considered its preferred embodiments, it is to be understood that the invention is not limited to that described above. To the contrary, the invention is intended to cover various modifications and equivalent arrangements within the spirit and scope of the appended claims.

What is claimed is:

1. A method for fabricating an ohmic contact layer on a ridge structure of a semiconductor device, comprising:
depositing ohmic contact material on a semiconductor wafer; and
creating the ridge with a first layer of photoresist material.

2. The method of claim 1, further comprising:
depositing a dielectric material layer on the ridge; and
depositing a second photoresist material layer on the dielectric layer.

3. The method of claim 2, further comprising:
opening the photoresist layer to expose the ohmic contact layer.

4. The method of claim 3, further comprising: removing any extra metal overhang to expose the ohmic contact material on the ridge.

5. The method of claim 1, wherein the ohmic contact material is deposited by sputtering.

6. The method of claim 1, wherein the ohmic contact material is deposited by vacuum evaporation.

7. The method of claim 1, wherein the ohmic contact material is deposited by chemical vapor deposition techniques.

8. The method of claim 1, wherein the ridge is created by etching.

9. The method of claim 2, wherein the dielectric material layer is deposited by plasma enhanced chemical vapor deposition technique.

10. The method of claim 2, wherein the dielectric material layer is deposited by vacuum evaporation.

11. The method of claim 2, wherein the dielectric material layer is deposited by sputtering.

12. The method of claim 2, wherein the photoresist material is deposited by plasma enhanced chemical vapor deposition technique.

13. The method of claim 3, wherein the photoresist material is opened by dry etching.

14. The method of claim 4, wherein the extra metal exchange is removed by ultrasonic techniques.

15. The method of claim 5, wherein the extra metal overhang is removed by solvent.

16. A semiconductor chip made using the process for fabricating an ohmic contact layer on a ridge structure of the semiconductor chip, comprising of:
depositing ohmic contact material on a semiconductor wafer; and
creating the ridge with a first layer of photoresist material.

17. The semiconductor chip of claim 16, further comprising:
depositing a dielectric material layer on the ridge; and
depositing a second photoresist material layer on the dielectric layer.

18. The semiconductor chip of claim 17, further comprising:
opening the photoresist layer to expose the ohmic contact layer.

19. The semiconductor chip of claim 18, further comprising: removing any extra metal overhang to expose the ohmic contact material on the ridge.

20. The semiconductor chip of claim 16, wherein the ohmic contact material is deposited by sputtering.

21. The semiconductor chip of claim 16, wherein the ohmic contact material is deposited by vacuum evaporation.

22. The semiconductor chip of claim 16, wherein the ohmic contact material is deposited by chemical vapor deposition techniques.

23. The semiconductor chip of claim 16, wherein the ridge is created by etching.

24. The semiconductor chip of claim 17, wherein the dielectric material layer is deposited by plasma enhanced chemical vapor deposition technique.

25. The semiconductor chip of claim 17, wherein the dielectric material layer is deposited by vacuum evaporation.

26. The semiconductor chip of claim 17, wherein the dielectric material layer is deposited by sputtering.

27. The semiconductor chip of claim 17, wherein the photoresist material is deposited by plasma enhanced chemical vapor deposition technique.

28. The semiconductor chip of claim 18, wherein the photoresist material is opened by dry etching.

29. The semiconductor chip of claim 18, wherein the extra metal exchange is removed by ultrasonic techniques.

30. The semiconductor chip of claim 20, wherein the extra metal overhang is removed by solvent.

31. A system containing a semiconductor chip made using the process for fabricating an ohmic contact layer on a ridge structure of the semiconductor chip, comprising of:
depositing ohmic contact material on a semiconductor wafer; and
creating the ridge with a first layer of photoresist material.

32. The system of claim 31, further comprising:
depositing a dielectric material layer on the ridge; and
depositing a second photoresist material layer on the dielectric layer.

33. The system of claim 32, further comprising:
opening the photoresist layer to expose the ohmic contact layer.

34. The system of claim 33, further comprising: removing any extra metal overhang to expose the ohmic contact material on the ridge.

35. The system of claim 31, wherein the ohmic contact material is deposited by sputtering.

36. The system of claim 31, wherein the ohmic contact material is deposited by vacuum evaporation.

37. The system of claim 31, wherein the ohmic contact material is deposited by chemical vapor deposition techniques.

38. The system of claim 31, wherein the ridge is created by etching.

39. The system of claim 32, wherein the dielectric material layer is deposited by plasma enhanced chemical vapor deposition technique.

40. The system of claim 32, wherein the dielectric material layer is deposited by vacuum evaporation.

41. The system of claim 32, wherein the dielectric material layer is deposited by sputtering.

42. The system of claim 32, wherein the photoresist material is deposited by plasma enhanced chemical vapor deposition technique.

43. The system of claim 33, wherein the photoresist material is opened by dry etching.

44. The system of claim 33, wherein the extra metal exchange is removed by ultrasonic techniques.

45. The system of claim 35, wherein the extra metal overhang is removed by solvent.
